(19) United States
(12) Patent Application Publication
(10) Pub. No.: US 2008/0264467 A1
(43) Pub. Date: Oct. 30, 2008

(54) Transportable System for Producing Solar Electricity

(76) Inventor: Gilbert Doko, Hannover (DE)

Correspondence Address: JORDAN AND HAMBURG LLP, 122 EAST 42ND STREET, SUITE 4000, NEW YORK, NY, 10168, US

(21) Appl. No.: 11/579,297

(22) PCT Filed: May 2, 2005
(86) PCT No.: PCT/DE2005/000878

§ 371 Date: Aug. 13, 2007

(30) Foreign Application Priority Data
May 6, 2004 (DE) 10 2004 023 043.9

(51) Int. Cl. H01L 31/042

(52) U.S. Cl. 136/245

(57) ABSTRACT

The invention relates to a transportable system for producing solar electricity, consisting of solar cells that are mounted in rectangular frames, a current transformer and a control device. The aim of the invention is to provide an efficient, mobile system for generating solar electricity, which can be rapidly erected and dismantled and is easy to transport. To achieve this: the solar modules of said system are interconnected by articulations and can be placed in a cradle, which protects them during transport and at least partially surrounds them in a folded state; the solar modules are connected to and held by a support that is mounted on the cradle, in such a way that said modules can be deployed and folded away; and said modules lie on the support in the deployed state and are additionally supported by telescopic legs that can be extended outside the cradle. The erection and dismantling of said system for generating solar electricity can be carried out rapidly and easily and the system can be placed in its cradle to protect it against damage during transport. The system can be erected easily by deploying the frames containing solar modules and can be transported by folding said frames. It does not require new cable connections at each new location, the cabling is carried out when the system is produced and is not touched again. The system can also be configured in such a way that the box containing the electrics and battery can be detached from and re-attached to the solar module unit, if electric energy is required only for a short period of time at another location.

### BACKGROUND OF THE INVENTION

The invention relates to a transportable system for generating solar power, consisting of solar modules, solar cells mounted in rectangular frames of aluminum, a device for transforming current and a control device.

Systems for generating solar power are mounted permanently on roofs and other substrates capable of bearing a load. Until now, there has been no reason for making aggregates, which generate solar power, mobile.

Solar systems, which are accommodated permanently on roofs of ships and can be unfolded on spaceships, form an exception.

Mobile power generating plants, operated with a liquid fuel, are used in undeveloped areas for supplying bridge and street building sites, in large forests for supplying hunting lodges, on sparsely populated islands for supplying the inhabitants living there and wherever it is impossible or on uneconomic to supply electric power over cables. This type of power generator is used during the day for operating implements, such as cranes, mixers, etc. and, at nighttime, for supplying energy to the crew quarters. These power generators produce much engine noise, which disturbs the crew when sleeping.

### SUMMARY OF THE INVENTION

The invention avoids the disadvantages of the state of the art. It is an object of the invention to create an efficient mobile installation for generating solar power, which can be set up and taken down quickly and transported easily.

The invention consists therein that the solar modules of this installation are connected to one another by links and can be accommodated in a rack, which protects them during transport and surrounds them at least partly when they are in the folded together state, and that they, being unfoldable and foldable, are connected with a carrier mounted at the rack and carried by the carrier, the solar modules resting in the unfolded state on the carrier and, being additionally supported by telescopable legs, which can be set up outside of the rack.

This installation for generating solar power can be set up and taken down easily and quickly and, for transport, accommodated in its frame protected against transport damage. The installation can be set up easily by unfolding the frames holding the solar modules and transported away by folding the frames together. It does not have to be wired again whenever the site is changed. Rather, the wiring is carried out once when the installation is produced and then is no longer touched.

The solar modules of this installation advantageously may be installed in the frames surrounding them and the links are mounted at the frames, which also accommodate the telescopable legs when the installation is in the folded together state.

Moreover, a frame, surrounding the solar module, may accommodate a second solar module, which is hinged to it but not surrounded by a frame. In this way, two solar modules at a time are located in a frame surrounding them, protected during transport. The sides of the solar modules, facing the sun, are turned towards one another in this transporting state and, as a result, are particularly protected.

Advantageously, the installation can be configured so that a series of frames, with solar modules installed within them, carry at their opposite sides the links, with which these frames are connected into a series and that a further solar module, which is not surrounded by a frame and can be folded into the frames, is hinged over links to each of these solar modules, which are surrounded by frames. Accordingly, the frames with links are connected with one another into a series of frames, which, when folded together, can easily be unfolded by one person, who can also, during the unfolding process, bring the legs into the required length and set them up. Once this series of framed solar modules is set up, the person can then subsequently unfold individually the second modules lying in the frames and set up and align their legs.

In order to be able to set up this installation in any geographic length and width, independently of the slope of the site, and to be able to adapt it to any position of the sun, it is advantageous if the carriers of the frames with solar modules are disposed pivotably in the rack.

Advantageously, the installation is configured so that the carrier of the solar modules and their frames is a U-shaped profile carrier, which is hinged at its one end to the rack and can be supported with its other end on the rack by means of a support, in order to be able to adjust it optimally to the position of the sun.

In the folded together state of the installation, the support may then be stored in the U-shaped profile of the carrier.

It is advantageous for this installation if the telescopable legs are disposed underneath the solar modules or the frame surrounding them or at places, at which solar modules adjoin one another.

This installation becomes particularly convenient, space saving during transport and easy to handle if the frames with solar modules are disposed parallel to one another with their edges aligned in the transporting state.

When folded apart, the solar modules of this installation form a plane with their frames in the operating state.

It is advantageous for the space-saving construction of this installation and for avoiding the wiring work as well as for the possibility of being able to have the installation operating very quickly, if the rack of this installation, in addition to the space for accommodating the frames with the solar modules, has a space for the control system, a space for the batteries and a space for the device for converting the current.

For damage-free transport, convenient handling and damage-free storage, and the rack will be U-shaped in cross section and open at the top as well as at the sides.

Alternatively, the electric and battery box may also be set up separately from the aggregate of the solar modules and used as a power supply, if the rack, at the boundary between the aggregate of the (folded together) solar modules, can be divided and the electric and battery box, and the electrical connection between the aggregate of the (folded together) solar modules and the electric and battery box is produced by a plug and socket connector or some other connection, and can be taken apart. This is of importance wherever the energy, stored in the electric and battery box, is to be used only briefly in order to return to the place of the erected and folded apart solar modules after the brief use. In that case, it is not necessary to convert these solar modules from their set up position into the folded together position before the brief use at a different place and, after the brief use, to fold them apart once again and set them up. Instead, the aggregate of the solar modules can continue to be used for generating power even in the absence of the electric and battery box, if the power and voltage converting elements in the electric and battery box or not required.

The essence of the invention is explained in greater detail below by means of an example, which is shown diagrammatically in the accompanying drawings.

### BRIEF DESCRIPTION OF THE DRAWINGS

FIG. 1 shows the installation folded together in the state in which it may be transported,

FIG. 2 shows the installation erected and set up in a horizontal plane,

FIG. 3 shows the installation erected and placed in the incident direction of the rays of the sun,

FIG. 4 shows the installation erected and mounted on a roof,

FIG. 5 shows a view of the rack from the front side,

FIG. 6 shows a view of the rack from the longitudinal side

FIG. 7 shows a view of the rack from the box side,

FIG. 8 shows a view of the rack from above,

FIG. 9 shows a front view of the loaded frame,

FIG. 10 shows a longitudinal view of the loaded rack,

FIG. 11 shows a view of the loaded rack from above,

FIG. 12 shows a view of the unfolded installation,

FIG. 13 shows a plan view of the unfolded installation,

FIG. 14 shows a side view of the unfolded installation,

FIG. 15 shows a rear view of the electric and battery box,

FIG. 16 shows a side view of the electric and battery box,

FIG. 17 shows a plan view of the electric and battery box,

FIGS. 18 to 21 show details of the carrier construction,

FIGS. 22 and 23 show details of the link connections,

FIGS. 24 and 25 show details of the fastening to the carrier,

FIG. 26 shows a perspective view of an installation with a dividable frame

FIG. 27 shows the installation of FIG. 26 with the assembled rack in a side view,

FIG. 28 shows the part of the installation of FIG. 26, carrying a solar modules, with the rack disassembled, in a side view,

FIG. 29 shows the part of the installation of FIG. 26, carrying electric and battery box, with the rack disassembled, in a side view,

FIG. 30 shows the part of the installation of FIG. 26, carrying the solar modules, with the rack disassembled, in a view from above,

FIG. 31 shows the part of the installation of FIG. 26, carrying the electric and battery box, with the rack disassembled, in a view from above,

FIG. 32 shows the part of the installation of FIG. 26, carrying the solar modules, with the rack disassembled, in a side view of the split plane,

FIG. 33 shows the part of the installation of FIG. 26, carrying the electric and battery box, with the rack disassembled, in a side view of the split plane,

FIG. 34 shows a detailed view of the split plane of the rack from the side, and

FIG. 35 shows a detailed view of the split plane of the rack from above.

### DESCRIPTION OF THE PREFERRED EMBODIMENTS

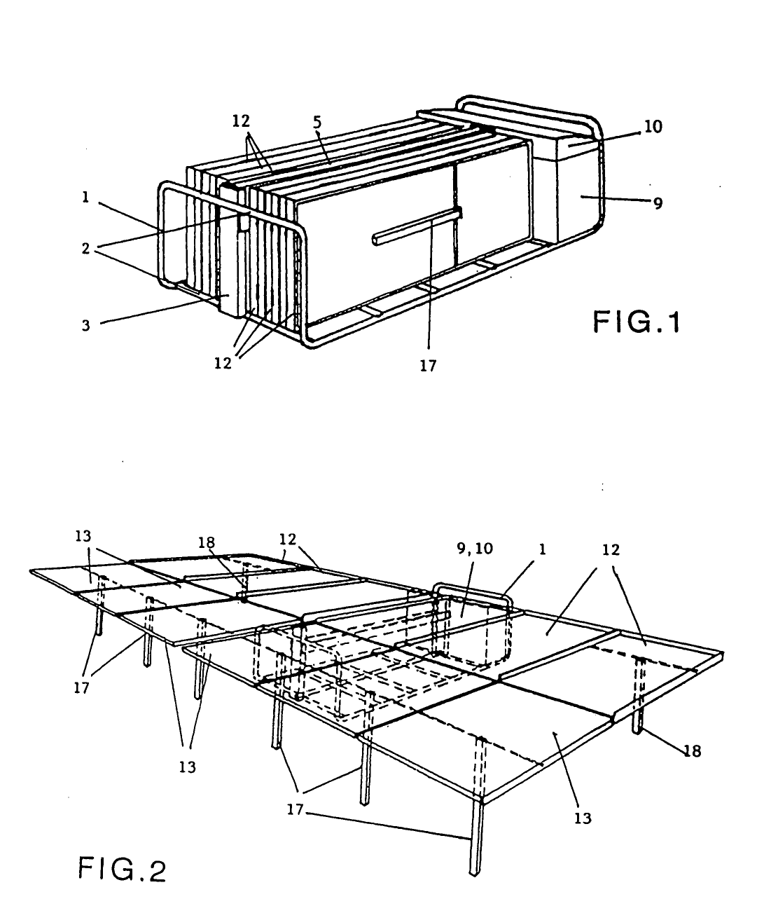

The rack 1, shown in FIG. 1, consists essentially of U-shaped steel pipes at the longitudinal side of the rack, which are welded together with transverse pipes 2. On either side of the U-shaped profile carriers 3, which are disposed centrally and vertically in the rack 1 and welded to the rack 1, there are frames 12, which are folded together and carry solar modules. Aside from these frames 12 with solar modules, the rack 1 also comprises a battery box 9 and an electric box 10, in which there are the electrical components for converting the direct current, generated in the solar modules, into forms of electric current required by the consumers (alternating current or three-phase current). In addition, a box, accommodating batteries, may be disposed here.

In FIG. 2, this installation is shown unfolded and set up in a horizontal plane. The individual frames 12 with solar modules are unfolded here and disposed in a row next to one another. Underneath them is the rack 1 with the battery box 9 and the electric box 10. The frames 12 with the solar modules rest, on the one hand, on the rack 1 and, on the other, on telescopable legs 18.

In each case, a further solar module 13 is unfolded from the frame 12. These solar modules 13 themselves, without frames, had also been located each in a frame 12 and are connected foldably by means of a link in each case with a solar module, which is disposed permanently in a frame 12. In the unfolded state of the installation, these solar modules 13 form a second row of solar modules. These solar modules 13 rest on telescopable legs 17. The telescopable legs 17, 18 are disposed approximately centrally underneath the solar modules 12, 13, which are assigned to them.

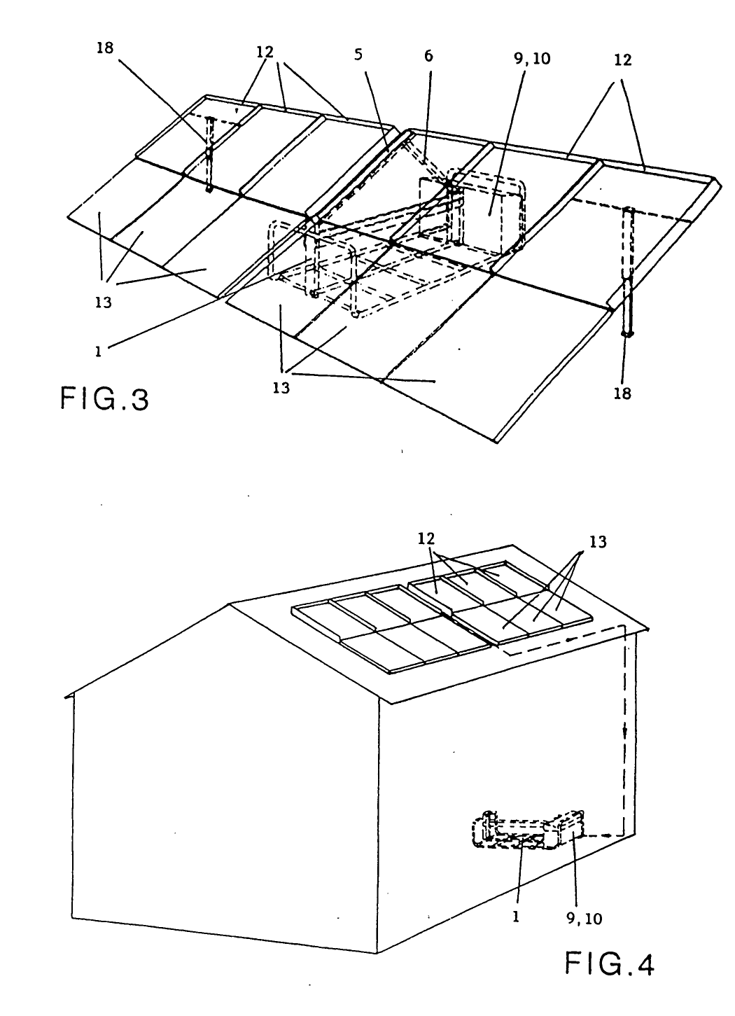

As shown in FIG. 3, this installation can also be adjusted in the direction of the incident sunlight. For this purpose, a carrier 5 of the frames 12 with solar modules, supported on the U-shaped profile carriers 3, is mounted in the center of the rack 1, so that it can be swiveled up. The carrier 5 can be secured in its swiveled position by a supporting beam 6.

For this installation, the wiring is such that, when the parts of this installation are brought into the positions of FIGS. 1, 2 and 3, no changes whatsoever have to be made in the placements of the cables and their connection to the components of the installation.

FIG. 4 shows that, for the installation, the frame 12 with the solar modules can be separated from the rack 1 with the battery box 9 and the electric box 10, in order to mount the frames 12 with the solar modules on the roof of a house.

The construction of the individual components of the installation is described in the following.

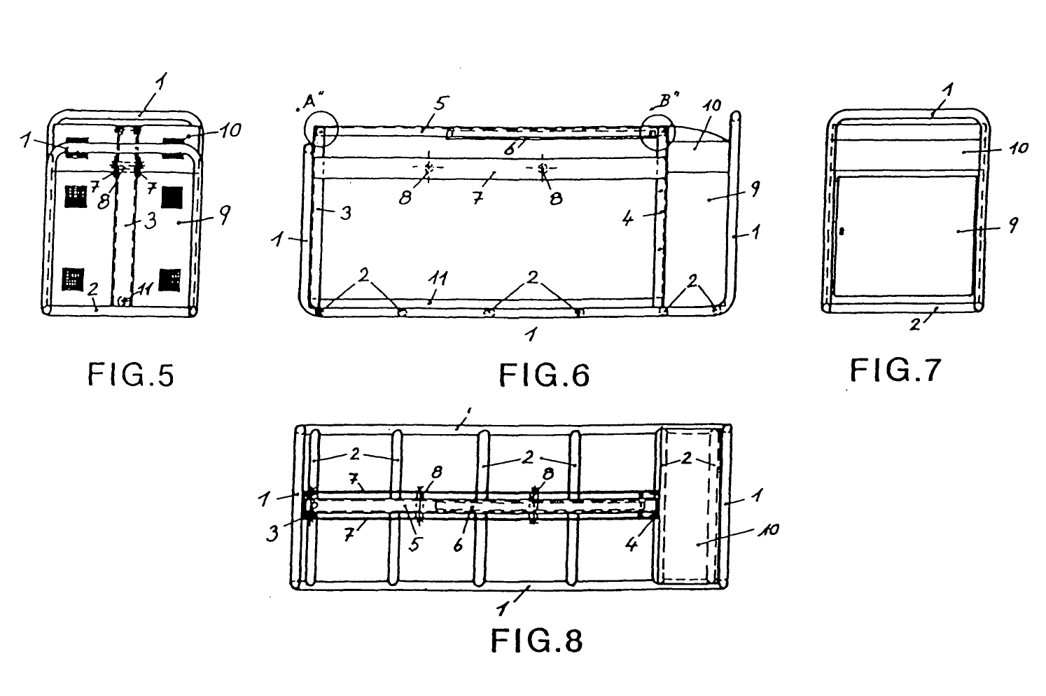

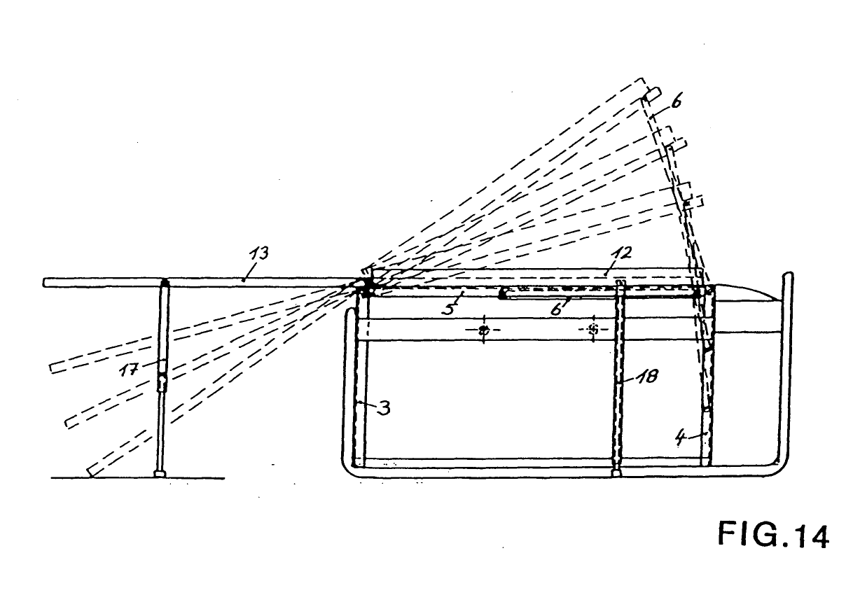

The details of the construction of the rack 1 are shown in FIGS. 5 to 8. It consists of two steel pipes, bent in the form of a U, forming the longitudinal side and welded and stiffened with steel pipes 2 of the same cross section. At their upper ends, two vertically disposed U-shaped profiles 3 and 4 accommodate the carrier 5 of a U-shaped profile, which carries the hinged and, accordingly, foldably connected frames 12. The supporting beam 6, which is hinged to the rack 1, is also hinged to the carrier 5 and rests between the flanges of the carrier 5, which is U-shaped in cross section, when the frame 12 is folded in with the solar modules is in the horizontal position. If the plane of the solar modules is to be in an inclined position, the supporting beam 6 is folded up from its position of respite between the flanges of the carrier 5, in that the lower end of the supporting beam 6 is fixed by means of a bolt with a splint (similar to detail “B”) in FIG. 19) in one of the boreholes of the U-shaped profile 4 (compare FIG. 14). At the top and at the bottom, the U-shaped profiles 3 and 4 are welded to the rack 1. For stiffening the rack 1, the U-shaped profiles 3 and 4 are connected together by two strips of sheet-metal 7, which have been welded on. The latter are supported in their third points by means of screws and spacer pipes 8. The battery box 9 is connected permanently, by welded seams, with the supporting frame 1, the stiffening pipes 2 of the supporting frame 1 and the U-shaped profile 4. The electric box 10, which contains the electrical components, is above the battery box, with which it is connected only by means of screws and can therefore, after the screws are loosened, be taken out of the installation. The cable pipe 11 is disposed between the lower ends of the U-shaped profiles 3 and 4 for the protected accommodation of the connecting cable between the solar modules and the battery box. The cables, passed down between the flanges of the U-shaped profile 3, are introduced through an opening at the upper side of the cable pipe 11 and emerge at the other end through an opening at the lower end of the U-shaped profile 4 into the adjoining battery box. All of the parts of the rack, described above, consist of hot-dip galvanized steel.

Examples of the inventive embodiments are given in FIGS. 2 and 13.

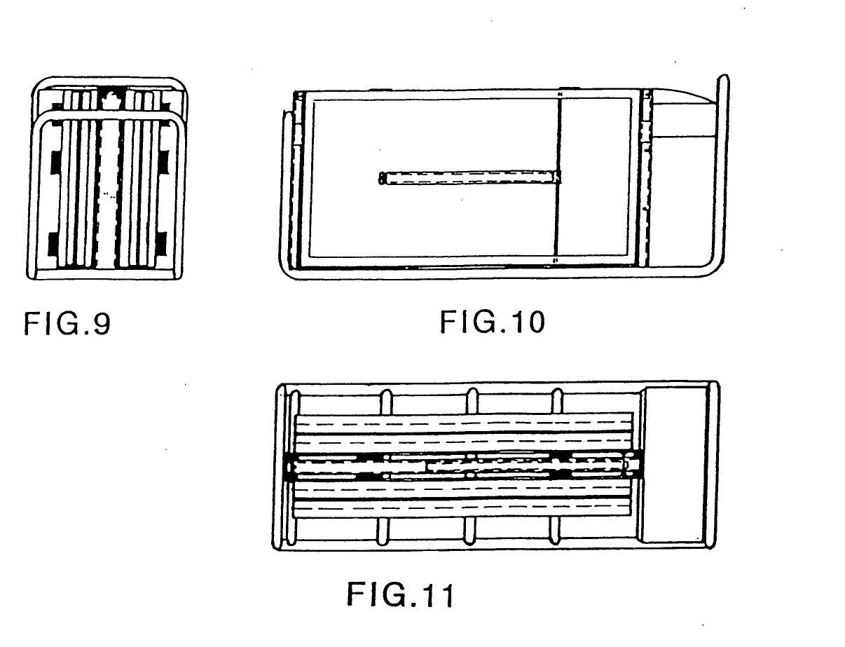

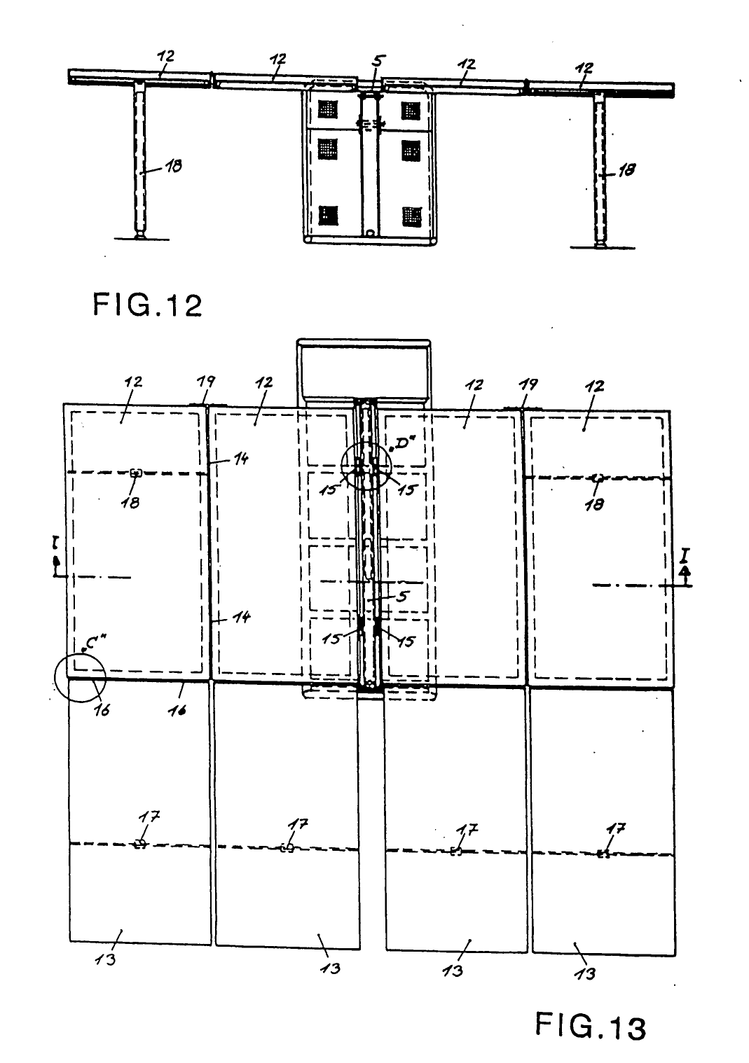

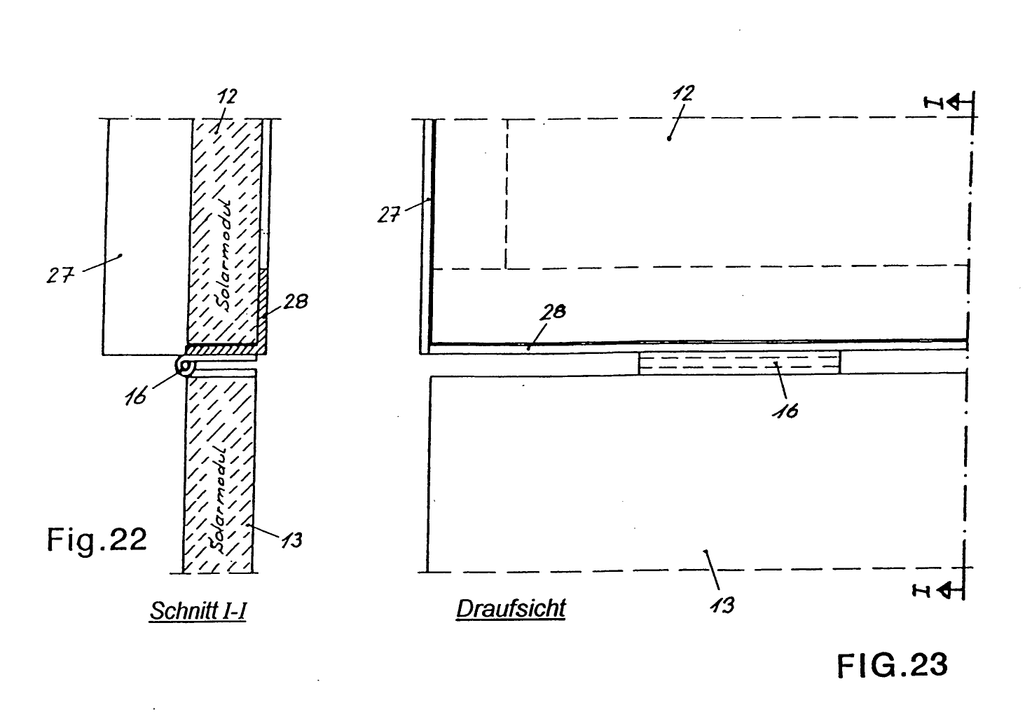

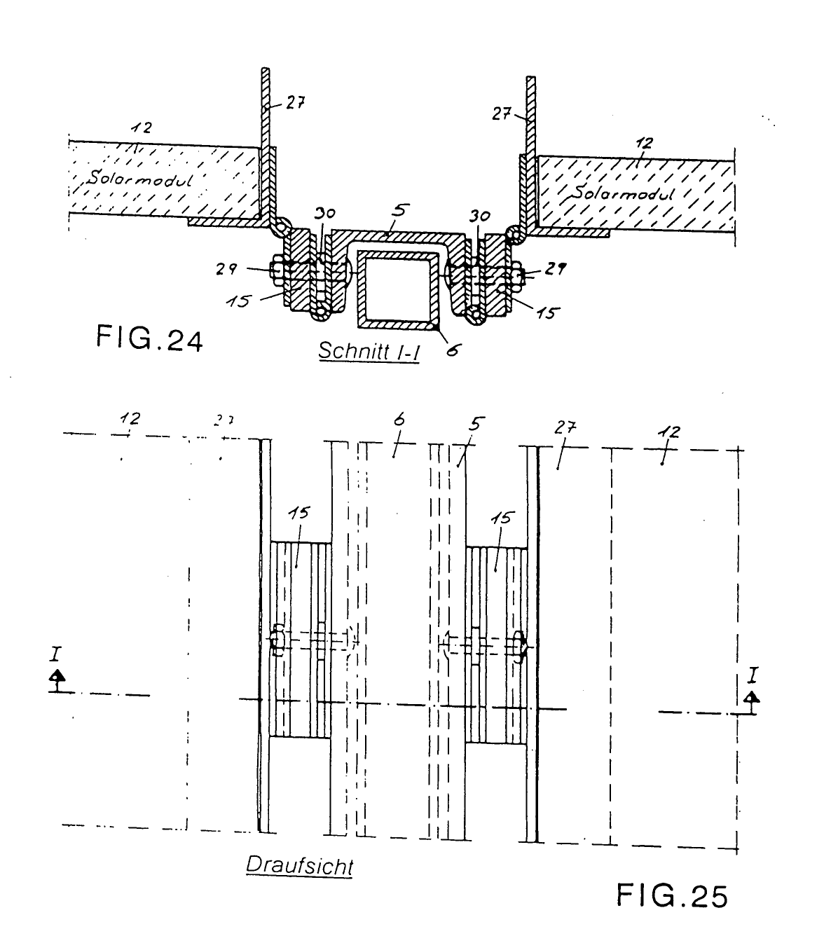

FIG. 2 shows the arrangement of the solar modules in the spread out, horizontal position, that is, in a state, where the sun is near its zenith. The solar module plane shown consists of 12 solar modules and is only an example. Planes of only 4 modules or of 16 molecules are also possible. Even larger planes can be realized. However, they require a wider rack construction. In the solar module folding system of FIG. 2, half of the existing solar modules are placed in individual frames 12 of angle iron and are fastened in them, while the remaining solar modules 13 remain without such frames. Along their longitudinal sides, adjacent, framed solar modules 12 are hinged together by, in each case, two hinges 14. They are added onto the carriers 5 by a special joint construction 15, which will be described in greater detail in connection with FIGS. 24 and 25. The solar modules 13, which are not framed, are connected over two hinges in each case at a narrow side of the framed solar modules 12 (see FIG. 22). In the spread-out state, the solar modules are supported by telescopic legs, which, when the solar module planes are folded in, are folded against the solar modules (see FIG. 14). Each solar module without a frame is supported by a telescopic leg 17, which is extended when the solar modules are in the horizontal plane and telescoped as required when the plane is inclined at an angle (see FIG. 14). For the solar modules mentioned, only the outer modules of framed solar modules are supported by telescopic legs 18, which are telescoped when the solar module plane is in the horizontal position and extended as required when the plane is in an inclined position (see FIG. 14). Locking systems 19 between neighboring modules are provided to stabilize framed solar modules, which are not supported. When the solar module planes are folded in, the solar modules 13, which are not framed, are first of all folders onto the framed modules 12. Then, after the locking systems 19 are unlocked, these module packets can be folded together like an accordion and secured against being pulled apart unintentionally by locking systems, so that the state, shown in FIG. 1 and in FIGS. 9 to 11, is reached.

FIG. 14 shows the whole system in side view with the solar module plane spread out in the horizontal position (continuous lines) and in 3 inclined positions (broken lines). For the horizontal position, the supporting beam 6 remains folded in and locked in the carrier 5 by means of a locking bolt (similar to the securing of the carrier 5, shown in FIG. 19). In this state, the carrier 5 also remains locked in the U-shaped profile 4, as shown in FIG. 19. To place the plane of the solar modules in an inclined position, this locking system for the carrier 5 is unlocked, the supporting beam 6 is folded out and its lower end is fixed in the desired inclined position by means of locking bolts in a pair of boreholes present in the U-shaped profile 4. The telescopic legs 17 and 18 are correspondingly telescoped or extended. Angles of inclination between 0° and 35° can be set with the construction shown in FIG. 14. The higher the position of the sun, the less is the inclination. At the equator, the horizontal position (0°) is regarded as optimal, whereas, for use in Europe, the optimum value ranges from 25° to 45° with a southerly alignment. In the present case, in order to obtain larger angles of inclination, only the U-shaped profiles 3 and 4 must be constructed longer, longer telescoping legs 17 and 18 must be provided and supporting carriers must be disposed on the supporting frame-stiffening carriers 2 for supporting the solar module packages, which have been folded together.

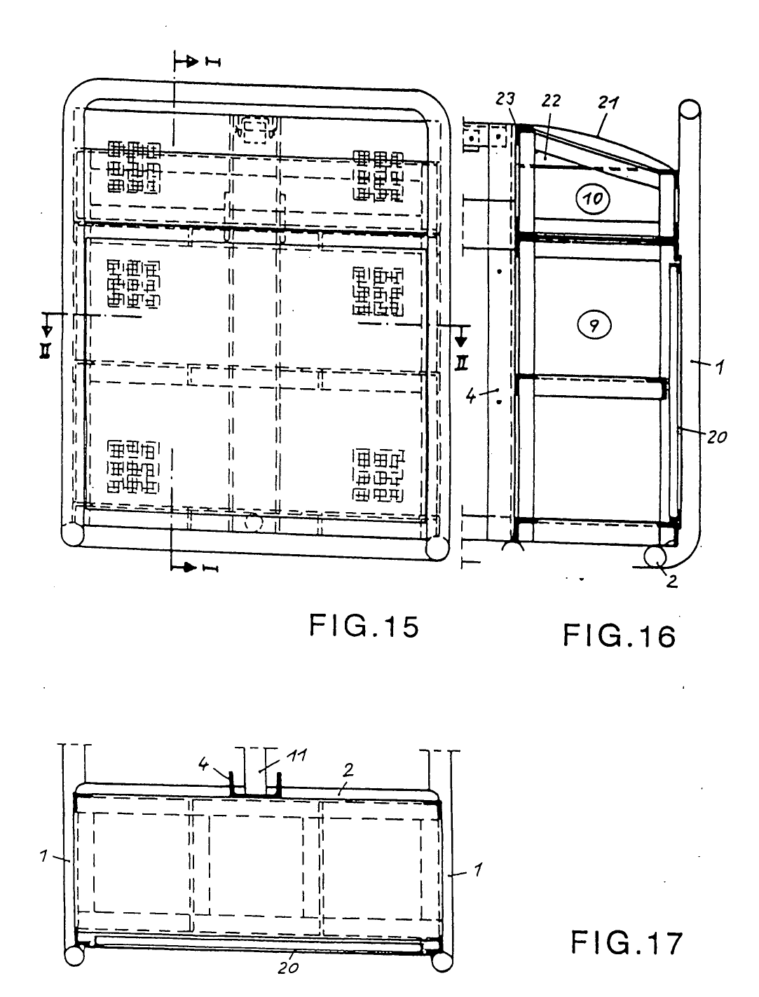

FIGS. 15 to 17 show the constructions of the battery box 9 and of the electric box 10. For the two, the supporting frame-work consists of steel connection angles, which are lined with sheet-metal (steel or the like). The battery box is welded to the adjoining pipe profiles of the rack 1 and the transverse pipes 2 and the U-shaped profile 4. Its front side is a door 20 of steel plate, reinforced by connection angles, which can be closed. In the back of the battery box, there are screen-shaped openings for ventilation. A further opening is located in the center of the lower end of the box for introducing the cable from the cable pipe 11. Solar batteries are accommodated in the battery box. These are gel batteries, which are maintenance free, omnidirectional, vibration resistant and shock resistant and do not form hydrogen and oxygen. On top of the battery box, there is the electric box, which contains the electrical components and is bolted to the battery box. After it is unbolted, the electric box can be taken out of the solar power generator and equipped separately from the generator with the appropriate electrical components. The possibility of being able to exchange the electric box without problems in the case of repairs or expansions for a different, previously prepared electric box, proves to be advantageous. The electric box has a curved lid 21, which can be tipped up and is reinforced at both ends by sheet-metal disks 22. At the rear of the electric box, the lead is hinged to the upper, horizontal angle of the supporting frame of the box at the spar 23 (see also FIG. 19). There are screen-shaped openings at the back of the electric box for venting.

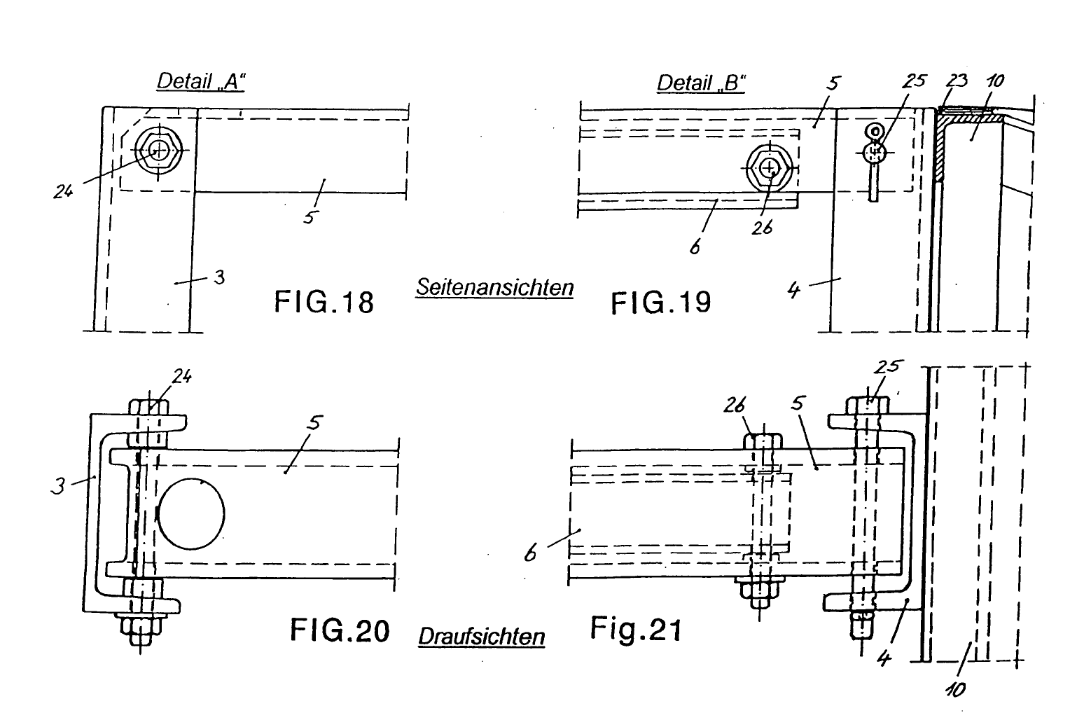

FIGS. 18 to 20 show the connections of the carrier 5 to the U-shaped profiles 3 and 4 as well as the connection of the supporting beam 6 to the carrier 5 as detailed points. The U-shaped carrier 5, which is open at the bottom, is connected with a pivot pin 24 to the upper end of the U-shaped profile 3 (FIG. 18). The end of the carrier 5 is beveled, so that there is no interference with the ability to rotate the carrier 5 when the solar module plane is placed in an inclined position. The other end of the carrier (FIG. 19) is fixed with a locking bolt with splint 25 in the uppermost pair of boreholes of the U-shaped profile 4. The supporting beam 5 is a hollow steel profile and is connected over a pivot pin 26 with the carrier 5. The other end of the supporting beam is fixed with a locking bolt (similar to 25) to the carrier 5. The procedure for placing the plane of the solar modules in an inclined position is described in the explanations of FIG. 14. If the folding solar module system is to be taken out of the rack for installation on a roof, only the bolts 24 and 25 have to be removed.

FIGS. 22 and 23 show the hinged connection 16 of a solar module 13, which is not framed, to a framed solar module 12 as a detail from FIG. 13. The frame construction of the module 12 consists on three sides of aluminum angle profiles 27 of an unequal length, the longer legs being at right angles to the plane of the modules. At the side, directed to the solar module that is not framed, an angular profile 28 with legs of equal length is provided, which enables the solar module 13, which is not framed, to be folded onto the framed solar module 12.

FIGS. 24 and 25 show the hinged connection 15 of two framed solar modules 12 to the carrier 5 as a detail from FIG. 13. The connection is characterized in that the angle profile 27 of the solar module frame, having legs of unequal length, is connected by means of a hinge to a metal intermediate piece 15, which, in turn, is fastened by a second hinge to the carrier 5. The metal intermediate pieces 15 are connected nonrotatably with bolts 29 and an interposed spacer disk 30 with the flanges of the carrier 5. If the folding solar module is to be installed separately from the rack on a roof, the bolts 29 are loosened, so that the intermediate pieces 15 can be rotated through 90°. The carrier 5 now no longer protrudes beyond the undersides of the solar modules, that is, the folding solar module system can be placed on the roof surface without further fillers.

Alternatively, the electric box and the battery box can also be set up separated from the aggregate of the solar modules and used as a power supply, if the rack can be divided at the boundary between the aggregate of the (folded together) solar modules and the electric box and battery box and the electrical connection between the aggregate of the (folded together) solar modules and the electric box and battery box is detachable due to the presence of a plug-and-socket connection.

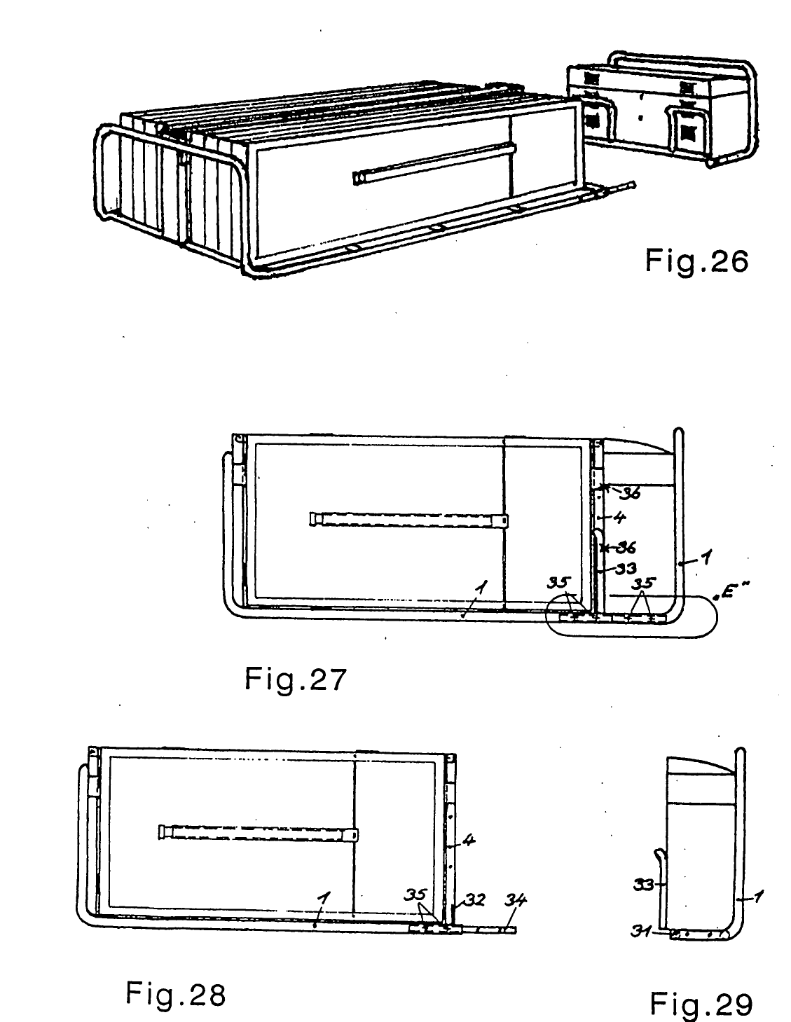

FIGS. 26 to 35 shown an embodiment of the inventive installation, for which the electric box and the battery box can also be set up separately from the aggregate of the solar modules and used as a source of power, since the rack can be divided at the boundary between the aggregate of the (folded together) solar modules and the electric box and battery box and the electrical connection between the aggregate of the (folded together) solar modules and the electric box and battery box is detachable due to the presence of a plug-and-socket connection or of a different severable connection.

FIG. 26 shows a perspective view of an installation with a rack, which can be divided in the plane, in which the solar modules adjoin the electric box and the battery box.

The reinforcing pipe 31 is welded in for reinforcing the rack in the region of the electric box and the battery box. The angle at the back of the bottom of the battery box is welded to this reinforcing pipe 31. The U-shaped profile carrier 4 is reinforced by means of two steel plates 32 welded on against the transverse pipe 2.

In order to make the electric box and battery box transportable, two carrying devices 33 of steel pipe are welded to the back. For coupling the two parts of the system, the planes of separation in the rack 1 are bridged by inserted pieces 34 of round steel, which are bolted to the rack 1 by means of hexagon screws 35 on either side of the planes of separation. The U-shaped profile carrier 4 is bolted by means of hexagon screws 36 to the profiles of the battery box.

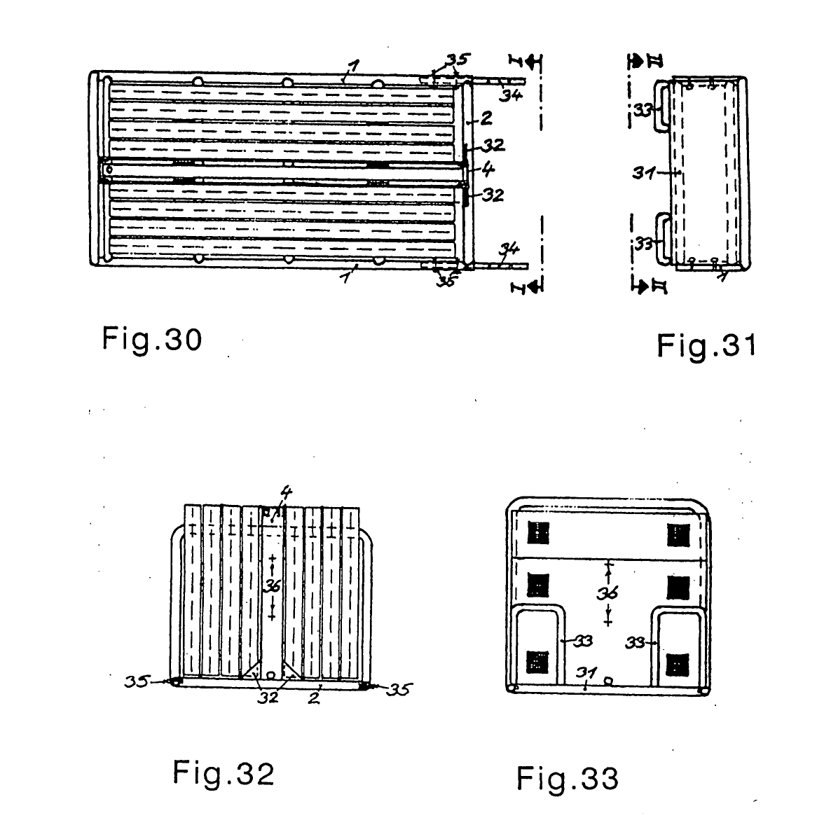

FIG. 27 shows the installation of FIG. 26 with the assembled rack in side view. FIG. 28 shows the part of the rack of the installation of FIG. 26, carrying the solar modules, with the rack disassembled in side view. FIG. 29 shows the part of the rack of the installation of FIG. 26, carrying the electric box and its battery box, with the rack disassembled in side view. FIG. 30 shows the part of the installation of FIG. 26, carrying the solar modules, with the rack disassembled in a view from above. FIG. 31 shows the part of the installation of FIG. 26, carrying the electric and battery box, with the rack disassembled in a view from above.

FIG. 32 shows a view of the part of the installation of FIG. 26, carrying the solar modules, starting from the plane of separation, with the rack disassembled.

FIG. 33 shows the part of the installation of FIG. 26, carrying the electric box and the battery box, with the rack disassembled, seen from the plane of separation.

The plane of separation extends in the rack 1 between a transverse pipe 2 and the reinforcing part 31, added in the region of the electric box and the battery box. The plane of separation is bridged by the piece 34 of round steel, which is bolted to the rack 1 to the left and right of the plane of separation by two hexagon screws 35 on each side. The nuts for the screws are welded to the rack 1. In order to separate the electric box and the battery box region from the remaining part of the system as a whole, the two screws to the right of the plane of separation are loosened. The carrying devices 33 belong to the carrying construction, which has been welded to the battery box.

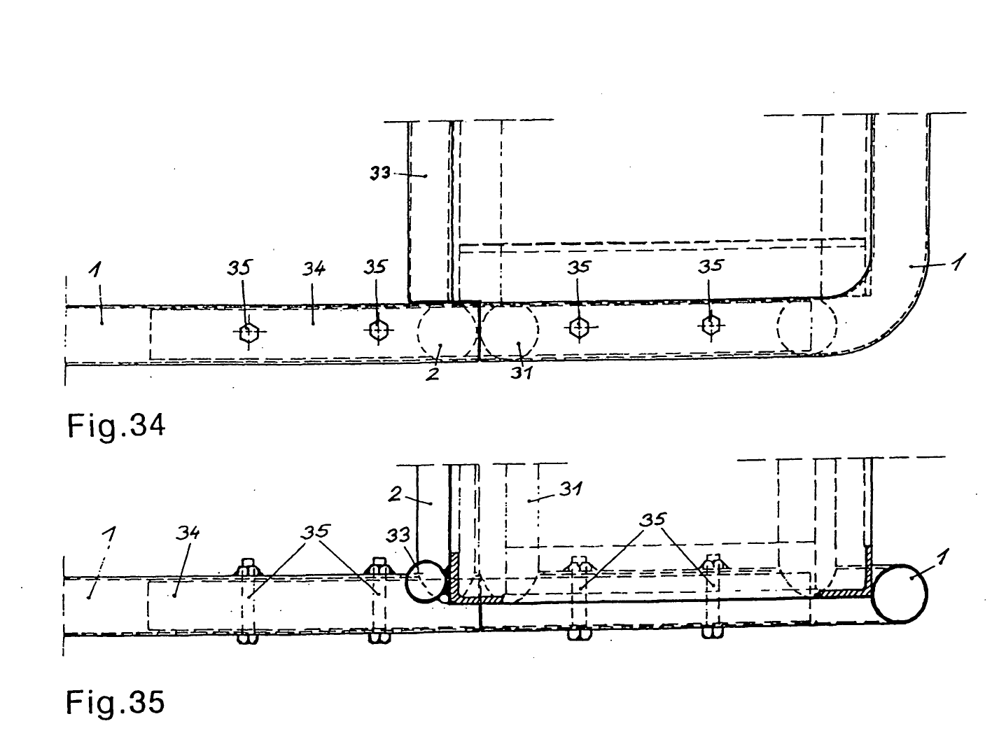

FIG. 34 shows a detailed side view of the dividing site of the rack.

FIG. 35 shows a detailed view of the dividing site of the rack from above.

### LIST OF REFERENCE SYMBOLS

1. rack
2. tranvers pipe
3. U-shaped profile carrier
4. U-shaped profile carrier
5. carrier of U-shaped cross section
6. supporting beam
7. sheet steel strip
8. spacer pipe
9. battery box
10. electric box
11. cable pipe
12. frame with installed solar module
13. solar module not framed
14. hinge
15. hinged connection
16. hinge
17. telescopic leg
18. telescopic leg
19. locking system
20. door
21. lid
22. metal disk
23. spar
24. pivot pin
25. splint
26. pivot pin
27. angle profile with the legs of unequal length
28. angle profile with the legs of equal length
29. bolt
30. spacer disk
31. stiffening pipe
32. sheet steel
33. carrying device
34. piece of round steel
35. hexagon screw
36. hexagon screw

1-14. (canceled)

15. A transportable system for generating solar power, comprising:
solar modules connected to one another by links so as to be unfoldable and foldable between an unfolded state and a folded together state;
frames which carry said solar modules;
a rack in which said solar modules are accommodatable, said rack protecting said solar modules during transport and at least partially surrounding said solar modules when said solar modules are in the folded together state;
a carrier being disposed on a side of the rack, to which the solar modules are connected, the solar modules resting on the carrier when in the unfolded state; and
telescopable legs mounted to said solar modules, which are disposed outside of the rack when in the unfolded state, and upon which the solar modules rest when in said unfolded state for additional support thereof.

16. A transportable system according to claim 15, wherein:
said solar modules are mounted in the frames, said frames at least partially surrounding said solar modules;
the links are provided at said frames, said frames also accommodating the telescopable legs in the folded together state.

17. A transportable system according to claim 15, wherein a one of the frames carrying a corresponding one of said solar modules, additionally accommodates a second one of said solar modules which is hinged to said one of said frames, and which is not surrounded by any of said frames.

18. A transportable system according to claim 15, wherein:
a series of said frames with ones of said solar modules installed within said series carry, at opposite sides thereof, the links with which said series of frames are mutually interconnected; and
a further solar module which is not surrounded by a one of said frames, and which is foldable into a one of the frames, is hinged to each of said ones of said solar modules surrounded by the one of said frames.

19. A transportable system according to claim 15, wherein the carrier of the solar modules and the frames corresponding thereto are disposed pivotably in the rack.

20. A transportable system according to claim 15, wherein the carrier of the solar modules and the frames corresponding thereto presents a generally U-shaped profile which is hinged at a one end thereof to the rack and is supportable at an other end thereof by a support carried on the rack.

21. A transportable system according to claim 20, wherein the support lies in the U-shaped profile of the carrier when in the folded together state.

22. A transportable system according to claim 15, wherein the telescopable legs are disposed under said solar modules or the frames surrounding said solar modules, or at places at which the solar modules adjoin one another.

23. A transportable system according to claim 15, wherein, in a transporting state, the frames with said solar modules are disposed parallel to one another, with edges thereof generally aligned.

24. A transportable system according to claim 15, wherein the frames with the solar modules lie in a common plane in an operating state.

25. A transportable system according to claim 15, wherein the rack is generally U-shaped in cross section and open at a top thereof as well as at sides thereof.

26. A transportable system according to claim 15, further comprising:
a device for converting current; and
a control device.

27. A transportable system according to claim 26, wherein the rack includes a space for the control device and a space for the device for converting current, in addition to a space for accommodating the frames with the solar modules.

28. A transportable system according to claim 15, further comprising an electric box and a battery box which is detachable from and joined together with a remaining aggregate of said transportable system.

29. A transportable system according to claim 28, wherein:
the rack is dividable at a plane between an aggregate of the solar modules in the folded together state and the electric box and the battery box; and
an electrical connection between the aggregate of the solar modules and the electric box and the battery box is detachable.
